(19) United States
(12) Patent Application Publication
(10) Pub. No.: US 2013/0230805 A1
(43) Pub. Date: Sep. 5, 2013

(54) DRAWING APPARATUS, REFERENCE MEMBER, AND METHOD OF MANUFACTURING ARTICLE

(71) Applicant: CANON KABUSHIKI KAISHA, Tokyo (JP)

(72) Inventors: Wataru Yamaguchi, Utsunomiya-shi (JP); Hideki Ina, Tokyo (JP); Satoru Oishi, Utsunomiya-shi (JP)

(73) Assignee: CANON KABUSHIKI KAISHA, Tokyo (JP)

(21) Appl. No.: 13/771,243

(22) Filed: Feb. 20, 2013

(30) Foreign Application Priority Data
Mar. 1, 2012 (JP) 2012-045783

(51) Int. Cl. H01J 37/317; G03F 7/00

(52) U.S. Cl. CPC H01J 37/3174; G03F 7/0035
USPC 430/296; 356/73; 428/192

(57) ABSTRACT

A drawing apparatus includes a charged particle optical system, a first measurement device including an image taking optical system and configured to measure a position of a reference mark in a first direction, a second measurement device configured to measure a position of the reference mark in the first direction based on an amount of charged particle beams that arrives thereat from the reference mark on which the charged particle beam are incident. The reference mark includes a first region having a first edge inclined with respect to a second direction perpendicular to the first direction and a second region having a second edge parallel to the second direction. A processor obtains a baseline based on measurement result with respect to the first region obtained by the first measurement device and measurement result with respect to the second region obtained by the second measurement device.

### BACKGROUND OF THE INVENTION

1. Field of the Invention

The present invention relates to a drawing apparatus, a reference member, and a method of manufacturing an article.

2. Description of the Related Art

In recent years, with an increase in packing density and miniaturization of semiconductor integrated circuits, the line width of a pattern formed on a substrate has become very small. To keep up with this trend, a lithography process in which a resist pattern is formed on a substrate requires finer patterning. The electron beam drawing scheme is known as one of methods which meet the requirement of such finer patterning.

An electron beam drawing apparatus (electron beam exposure apparatus) converges an electron beam on a desired position upon a substrate, and moves the electron beam and a stage, on which the substrate is mounted, relative to each other to draw a desired pattern on the substrate. For this reason, to form a fine pattern, it is of prime importance to align the electron beam and the target portion on the substrate with each other with the highest possible accuracy.

Japanese Patent No. 4454706 proposes a drawing apparatus that uses a light measurement device which measures the position using light, and an electron measurement device which detects the amount of incoming electrons, in order to align an electron beam and a substrate with each other. The electron beam drawing apparatus disclosed in Japanese Patent No. 4454706 aligns the electron beam and the substrate with each other, based on the result of measuring the position of an alignment mark on the substrate using the light measurement device, and the result of measuring the position of a reference mark on a stage using both the light measurement device and the electron measurement device.

To perform alignment using the light measurement device, it is necessary to periodically obtain the positional relationship (baseline) between the optical axis of the optical system of the light measurement device and the (optical) axis of an electron optical system, using the reference mark. This makes it indispensable to measure the baseline with high accuracy.

One factor which degrades the baseline measurement accuracy is the influence of a quantization error generated by the light measurement device. In general, the light measurement device irradiates a mark with light to form an image of the mark on the image taking surface of a photoelectric conversion element using light diffracted or scattered by the mark, thereby detecting the position of the mark. However, when the mark position is detected using a detection signal obtained by the photoelectric conversion element, the measurement accuracy degrades due to the influence of a quantization error generated as the detection signal is A/D-converted.

To solve this problem, a technique for reducing a quantization error generated by the light measurement device has been proposed. Japanese Patent Laid-Open No. 2001-53000 describes a light measurement device which detects a plurality of mark positions upon minutely displacing an optical member, which forms the light measurement device. The light measurement device disclosed in Japanese Patent Laid-Open No. 2001-53000 can cancel a quantization error, if it has a sinusoidal wave shape, by measuring the mark at two positions separated by an amount corresponding to a half of each pixel of the photoelectric conversion element, and summing the measurement values obtained at the respective positions.

Japanese Patent Laid-Open No. 6-347215 describes a technique of detecting the position of a mark while its widthwise direction (measurement direction) is inclined with respect to the longitudinal direction of photoelectric conversion elements which align themselves on a straight line. The position detection technique disclosed in Japanese Patent Laid-Open No. 6-347215 can reduce a quantization error practically by improving the pixel resolution of the photoelectric conversion elements.

The light measurement device disclosed in Japanese Patent Laid-Open No. 2001-53000 detects a plurality of mark positions upon minutely displacing the optical member. Hence, it takes a considerable time to displace the optical member, and that to detect the mark at a plurality of positions, thus prolonging the baseline measurement time.

Japanese Patent Laid-Open No. 6-347215 describes a mark with a widthwise direction inclined with respect to the longitudinal direction of the photoelectric conversion elements, but does not describe how to measure the position of the mark using the electron measurement device.

### SUMMARY OF THE INVENTION

The present invention provides, for example, a drawing apparatus advantageous in baseline measurement.

The present invention in its one aspect provides a drawing apparatus which performs drawing on a substrate with a charged particle beam, the apparatus comprising: a charged particle optical system configured to emit a charged particle beam onto the substrate; a stage including a reference mark, and configured to hold the substrate and to be movable; a first measurement device including an image taking optical system that takes an image of the reference mark with light, and configured to measure a position of the reference mark in a first direction perpendicular to an axis of the charged particle optical system; a second measurement device configured to measure a position of the reference mark in the first direction, based on an amount of charged particle beams that arrives thereat from the reference mark on which the charged particle beam emitted from the charged particle optical system are incident; and a processor configured to obtain a positional relationship between an optical axis of the image taking optical system and the axis of the charged particle optical system based on outputs from the first measurement device and the second measurement device, wherein the reference mark includes a first region having a first edge inclined with respect to a second direction perpendicular to the first direction and the axis of the charged particle beam optical system, and a second region having a second edge parallel to the second direction, and the processor is configured to obtain the positional relationship based on the measurement result with respect to the first region obtained by the first measurement device, and the measurement result with respect to the second region obtained by the second measurement device.

Further features of the present invention will become apparent from the following description of exemplary embodiments with reference to the attached drawings.

### BRIEF DESCRIPTION OF THE DRAWINGS

FIGS. 1A to 1C are views showing reference marks;

FIG. 2 is a view showing an electron beam drawing apparatus;

FIGS. 3A and 3B are views for explaining a quantization error;

FIGS. 4A and 4B are graphs showing how to measure the mark position using a light measurement device;

FIGS. 5A and 5B are graphs showing how to measure the mark position using an electron measurement device;

FIG. 6 is a flowchart showing the procedure of baseline measurement according to the first embodiment; and

FIG. 7 is a flowchart showing the procedure of baseline measurement according to the second embodiment.

### DESCRIPTION OF THE EMBODIMENTS

Embodiments of the present invention will be described below with reference to the accompanying drawings. Note that the same reference numerals denote the same members throughout the drawings, and a repetitive description thereof will not be given.

### First Embodiment

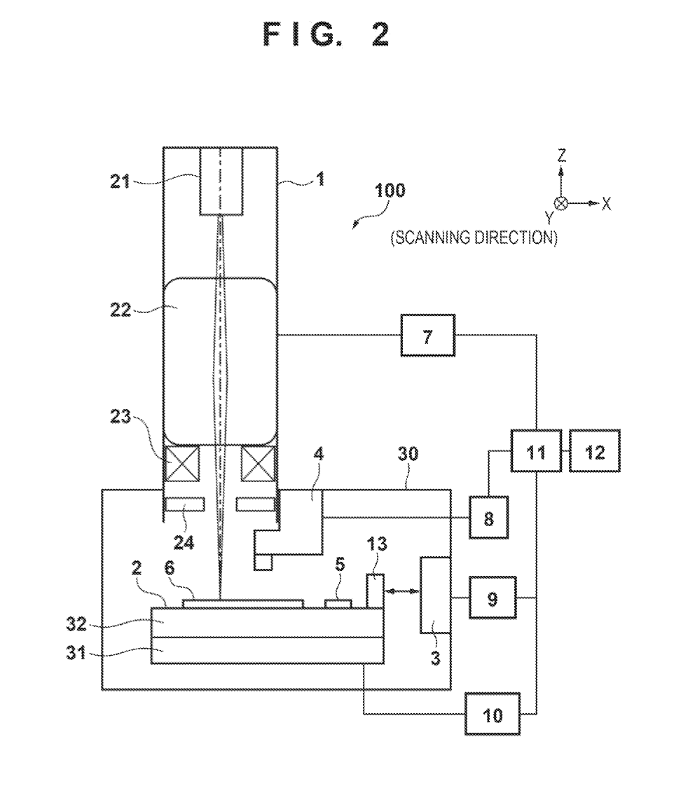

FIG. 2 is a view showing a drawing apparatus 100 which performs drawing on a substrate using an electron beam as a charged particle beam. The drawing apparatus 100 mainly includes an electron gun 21, an electron optical system (charged particle optical system) 1, an electron measurement device (second measurement device) 24, a stage 2 movable upon holding a substrate 6, a distance measurement interferometer 3, a light measurement device (first measurement device) 4, and a vacuum chamber 30. The light measurement device 4 includes an image taking optical system. The vacuum chamber 30 is evacuated to a vacuum by a vacuum pump (not shown). The vacuum chamber 30 accommodates the electron gun 21, electron optical system 1, electron measurement device 24, stage 2, distance measurement interferometer 3, and light measurement device 4.

The electron optical system 1 includes an electron lens system 22 which converges an electron beam emitted by the electron gun 21, and a deflector 23 which deflects the electron beam, and forms an image of the electron beam on the substrate 6. An electron optical system controller 7 controls the electron gun 21, electron optical system 1, and electron measurement device 24. In drawing a pattern on the substrate 6 using the electron beam, the electron optical system controller 7 scans the electron beam in the X-direction using the deflector 23, and controls the irradiation of the electron beam in accordance with the pattern to be drawn. In measuring the position of the substrate 6 using the electron beam, the electron optical system controller 7 scans the electron beam on the substrate 6 using the deflector 23, and detects secondary electrons, emitted by the substrate 6, using the electron measurement device 24 to obtain the position of the substrate 6.

The stage 2 has a configuration in which an X-stage 32 is located on a Y-stage 31, and the substrate 6 coated with a photosensitive material is held on the X-stage 32. A reference plate (reference member) including a reference mark 5 formed at a position different from that of the substrate 6 is set on the X-stage 32, and an X-moving mirror 13 is set at one end of the surface of the X-stage 32 in the X-direction. The Y-stage 31 positions the substrate 6 in the Y-direction, perpendicular to the paper surface of FIG. 2, within a plane perpendicular to the axis of the electron lens system 22. The X-stage 32 positions the substrate 6 in the X-direction perpendicular to the Y-axis within the plane perpendicular to the axis of the electron lens system 22.

A Z-stage (not shown) which positions the substrate 6 in the Z-direction parallel to the axis of the electron lens system 22 is also set on the X-stage 32. A stage controller 10 controls the Y-stage 31 and X-stage 32. The drawing apparatus scans the electron beam in the X-direction and scans the stage 2 in the Y-direction to draw a pattern on the substrate 6. For this reason, the Y-direction (second direction) parallel to the surface of the substrate 6 in FIG. 2 will be referred to as the scanning direction hereinafter, and the X-direction (first direction) will be referred to as the non-scanning direction hereinafter. The X-direction also serves as the measurement direction in which the light measurement device 4 measures the position of the reference mark 5.

The distance measurement interferometer 3 splits laser light emitted by an internal laser light source into measurement light and reference light. The measurement light is incident on the X-moving mirror 13 set on the stage 2, while the reference light is incident on a reference mirror built into the distance measurement interferometer 3, so that the reflected measurement light and reference light interfere with each other in superposition, and the intensity of the interfering light is detected using a detector. In the stage of emission, the measurement light and the reference light have frequencies different by a minute amount Δf, so the light measurement device 4 outputs a beat signal having a frequency that has changed from Δf in accordance with the moving speed of the X-moving mirror 13 in the X-direction.

The beat signal is processed by a stage position detector 9 to measure the amount of change in optical path length of the measurement light with reference to that of the reference light, that is, the X-coordinate of the X-moving mirror 13 with reference to that of the reference mirror, at a high resolution and high accuracy. Similarly, the Y-coordinate of a moving mirror set on the stage 2 with reference to that of a reference mirror is measured at a high resolution and high accuracy by a distance measurement interferometer (not shown) which detects the position of the stage 2 in the Y-direction.

The light measurement device 4 illuminates an alignment mark on the substrate 6 and the reference mark 5 formed on the stage 2 with, for example, light in a wavelength range which does not expose a resist to light to form an image of light beams reflected by these marks on the image taking surface, thereby measuring the positions of these marks. A light measurement device controller 8 obtains the mark position relative to the optical axis of the light measurement device 4. A main controller 11 processes the data from the electron optical system controller 7, light measurement device controller 8, stage position detector 9, and stage controller 10 to, for example, issue a command to each controller. A memory 12 stores information required for the main controller 11.

Although the drawing apparatus 100 draws a desired pattern at a plurality of shot regions on the substrate 6 basically by a step-and-repeat operation, it may draw this pattern upon scanning the substrate 6 and deflecting the electron beam. In drawing a desired pattern on the substrate 6 set on the stage 2 upon deflecting the electron beam, the reference position of the electron beam relative to the substrate 6 is corrected by controlling the deflector 23 which deflects the electron beam with movement of the stage 2, and controlling the position of the stage 2.

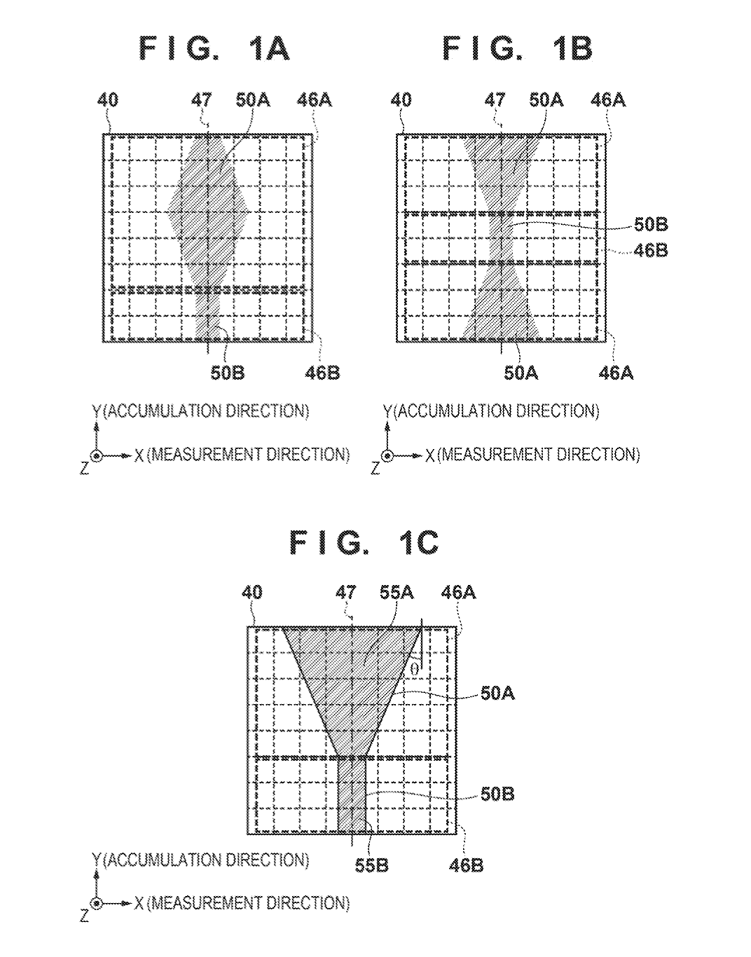

In this embodiment, the reference mark 5 includes both a first pattern (first region) 50A and second pattern (second region) 50B, as shown in FIGS. 1A to 1C. The first pattern 50A has edges (first edges) inclined with respect to the Y-direction (second direction). The second pattern 50B has edges (second edges) parallel to the Y-direction (second direction). Each of the first pattern 50A and second pattern 50B is axisymmetric about a line parallel to the Y-direction. Also, the axisymmetric axis of the first pattern 50A and that of the second pattern 50B are a common axis 47. The main controller 11 obtains the positional relationship (baseline) between the optical axis of the light measurement device 4 and the axis of the electron optical system 1 based on the measurement result of the first pattern obtained by the light measurement device 4, and that of the second pattern obtained by the electron measurement device 24. Hence, the drawing apparatus according to the first embodiment can perform baseline measurement at high speed and high accuracy, and align the electron beam and the substrate 6 at high speed and high accuracy. The reason why this is possible will be explained in detail below.

The shape of the first pattern 50A can be axisymmetric about an axis parallel to the non-scanning direction (X-direction) of the stage 2, as shown in FIGS. 1A and 1B. In the reference mark 5 shown in FIG. 1B, the first pattern 50A is formed to sandwich the second pattern 50B from the two sides along the Y-direction. In the reference marks 5 shown in FIGS. 1A and 1B, even if a rotation shift of the stage 2 occurs in the X-Y plane, it can be calculated and corrected by confirming the symmetry about an axis parallel to the X-direction at the positions of the edges of the first pattern 50A. Hence, the positions of the reference marks 5 shown in FIGS. 1A and 1B can be measured with an accuracy higher than that when the reference mark 5 shown in FIG. 1C is used. To avoid complications, the first embodiment in which the reference mark 5 shown in FIG. 1C, that clearly exemplifies a feature of the present invention, will be described below.

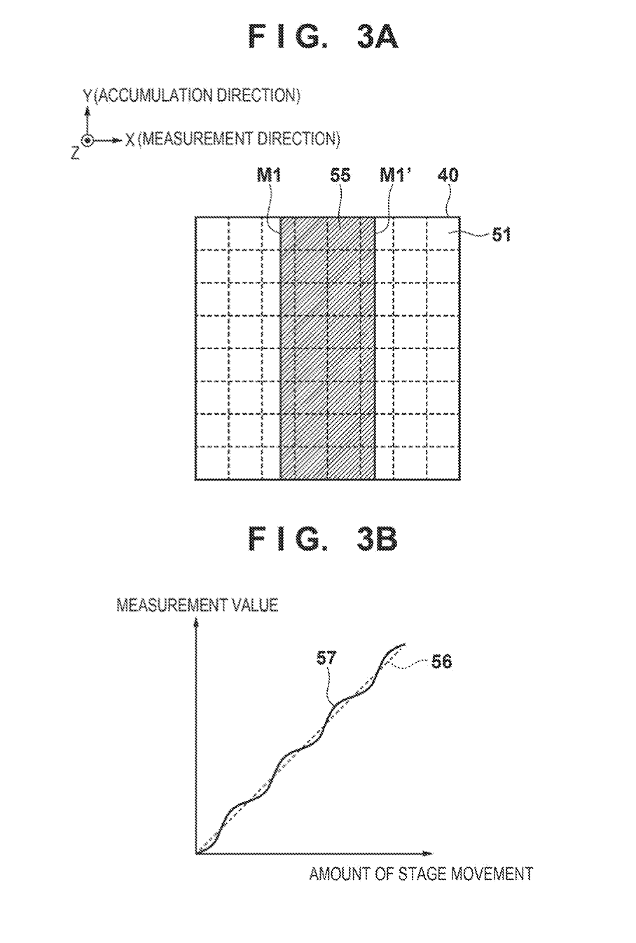

The influence of a quantization error generated by the light measurement device 4 will be described in detail with reference to FIGS. 3A and 3B. FIG. 3A is a view showing an image 55 of a mark pattern formed on the image taking surface of a photoelectric conversion element 40. The photoelectric conversion element 40 normally has a structure in which rectangular pixels 51 with a finite size are arranged at a pitch equivalent to the pixel size. The pixel size of the photoelectric conversion element 40 used in the light measurement device 4 is several hundred nanometers to several ten micrometers, although it varies depending on the imaging magnification of the optical system. Referring to FIG. 3A, the accumulation direction (Y-direction) of the photoelectric conversion element 40, that also serves as the scanning direction of the substrate 6, coincides with the longitudinal direction of the mark pattern. The measurement direction (X-direction) of the photoelectric conversion element 40 coincides with the widthwise direction of the mark pattern.

From the foregoing description, the direction in which edges M1 and M1′ of the image 55 of the mark pattern extend is parallel to the accumulation direction of the photoelectric conversion element 40. This means that the position of each edge of the mark pattern is detected by pixels having the same incident positions in the measurement direction (X-direction) (pixels which align themselves in the accumulation direction). In measuring the mark position, the main controller 11 detects the positions of the two side edges M1 and M1′ of the image 55 of the mark pattern using the photoelectric conversion element 40. Upon this operation, the main controller 11 calculates the center position of the mark pattern to obtain the position of a mark formed by a plurality of mark patterns.

The quantization error means an error generated when the positions of the edges M1 and M1′ of the mark pattern are detected by the pixels 51 with a finite size, and the detection signals are approximated in A/D conversion. When, for example, the stage 2 is driven to move the image of the mark pattern in an amount smaller than the pixel size of the photoelectric conversion element 40, a shift occurs between the mark measurement value and the amount of movement of the stage 2 in FIG. 3B due to the influence of the quantization error. FIG. 3B shows the relationship between the mark measurement value and the amount of movement of the stage 2 in an ideal case wherein no quantization error is generated, and in the case wherein a quantization error is generated, using a dotted line 56 and a solid curve 57, respectively. If a quantization error is generated, its amount often corresponds to an integral submultiple of the pixel size. Accordingly, in alignment of the substrate 6, which requires a measurement accuracy on the order of nanometers, the quantization error may become a significant cause of degradation in alignment accuracy in that case.

The configuration of the reference mark 5 according to the first embodiment will be described below with reference to FIG. 1C. FIG. 1C shows an image of the pattern of the reference mark 5 formed on the image taking surface of the photoelectric conversion element 40 in baseline measurement by the drawing apparatus. The reference mark 5 includes a first pattern 50A having edges inclined in the accumulation direction (Y-direction) of the photoelectric conversion element 40, and a second pattern 50B having edges parallel to the scanning direction (Y-direction) of the stage 2. The first pattern 50A and second pattern 50B have axisymmetric axes (center lines) on the same line, which are parallel to the scanning direction (Y-direction) of the stage 2. Referring to FIG. 1C, reference numerals 55A and 55B denote images of the first pattern 50A and second pattern 50B, respectively, formed on the image taking surface of the photoelectric conversion element 40; 47, the center line of the pattern; and 46A and 46B, the measurement regions of the first pattern 50A and second pattern 50B, respectively, in the light measurement device 4.

The reference mark 5 shown in FIG. 1C serves as an X-measurement mark for measuring the position information in the X-direction. In position measurement in the Y-direction, this is done using a Y-measurement mark having a pattern with a center line perpendicular to the scanning direction (Y-direction) of the stage 2. In the present invention, since the reference mark 5 can be used as both an X-measurement mark and a Y-measurement mark, only the configuration of the X-measurement mark will be described herein.

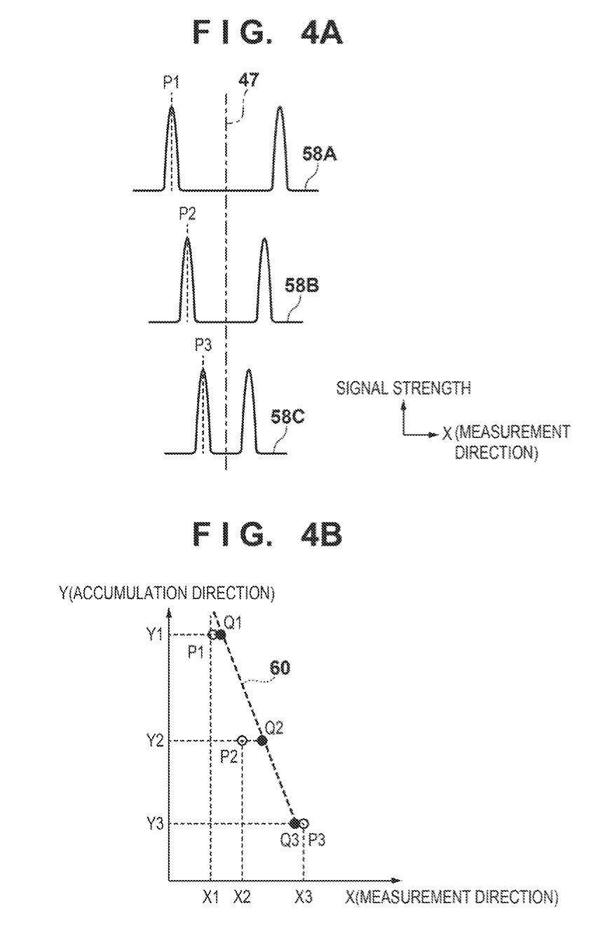

A method of reducing the quantization error in the image 55A of the first pattern 50A will be described with reference to FIGS. 4A and 4B. As described above, if the edges of the pattern are parallel to the accumulation direction of the photoelectric conversion element 40, the measurement accuracy degrades due to the influence of the quantization error. In contrast to this, in the reference mark 5 shown in FIG. 1C, the edges of the image 55A are inclined only by an angle θ with respect to the accumulation direction of the photoelectric conversion element 40. Hence, pixels 51 having different incident positions in the measurement direction can detect the positions of the edges of the image 55A of the first pattern 50A, for each position in the accumulation direction. FIG. 4A shows differential waveforms 58A to 58C of detection signals obtained at respective measurement positions in the accumulation direction of the photoelectric conversion element 40. In the individual differential waveforms 58A to 58C, the interval between two peaks varies depending on the measurement position in the accumulation direction, because the edges of the image 55A of the first pattern 50A are inclined by the angle θ with respect to the accumulation direction. Note that referring to FIG. 4A, reference symbols P1 to P3 each denote the position of one of the two peaks in each differential waveform.

FIG. 4B shows the coordinates of the peak positions P1 to P3 (open circles) on the detection surface of the photoelectric conversion element 40, that is, the coordinates X1 to X3 of the positions of the edges of the image 55A of the first pattern 50A corresponding to the positions Y1 to Y3 in the accumulation direction. Reference numeral 60 denotes an approximation line with a slope Φ obtained using the least-squares method based on the coordinate positions (Xi, Yi) of the peak positions P1 to P3, and reference symbols Q1 to Q3 (filled circles) denote points at the Y-coordinates Yi of the peak positions P1 to P3 on the approximation line 60. In the configuration of the reference mark 5 according to this embodiment, the positions of the edges of the pattern can be detected by the pixels 51 set at different positions in the measurement direction. Hence, by correcting the measurement result using the approximation line 60, the quantization error can be kept smaller so as to measure the mark position with a higher accuracy, compared to the case wherein a mark having a pattern with edges parallel to the accumulation direction of the photoelectric conversion element 40 is measured.

In calculating the center position of the mark pattern, this center position is done for each position in the accumulation direction, based on the positions of the two side edges of the image 55A of the first pattern 50A corrected using the approximation line 60. The pattern matching method or the moment method, for example, can be used. By calculating the average of the center positions of the mark pattern for respective positions in the accumulation direction, the center position of the image 55A of the first pattern 50A is obtained. It is therefore desired to set the center line of the first pattern 50A parallel to the accumulation direction of the photoelectric conversion element 40. If the center line of the first pattern 50A is not parallel to the accumulation direction of the photoelectric conversion element 40, the center position of the mark pattern in the accumulation direction changes in the measurement direction of the photoelectric conversion element 40. This makes it difficult to obtain the center position of the mark pattern by an averaging process with high accuracy. Hence, to allow high-accuracy measurement, the center line of the first pattern 50A is set parallel to the accumulation direction of the photoelectric conversion element 40.

The edges of the first pattern 50A are inclined by the angle θ with respect to the accumulation direction of the photoelectric conversion element 40, as shown in FIG. 1C. Accordingly, if the center line of the first pattern 50A is parallel to the accumulation direction of the photoelectric conversion element 40, the line width of the first pattern 50A varies in the accumulation direction of the photoelectric conversion element 40.

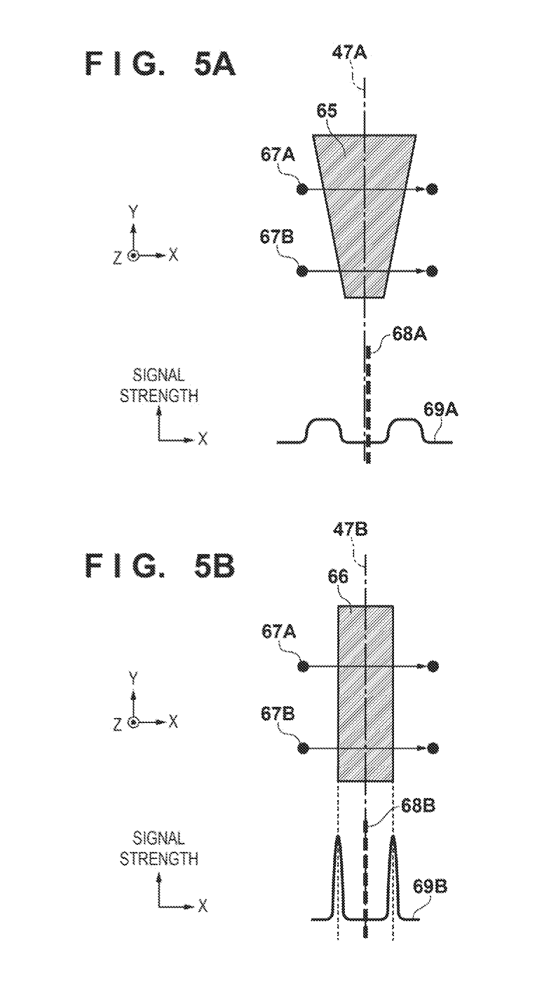

The role of the second pattern 50B shown in FIG. 1C will be described. In obtaining the baseline, the position of the reference mark 5 must be measured not only by measuring the mark position using the light measurement device 4, but also by scanning the electron beam relative to the reference mark 5 on the stage 2 to detect secondary electrons using the electron measurement device 24. In measuring the mark position using the electron beam, the wavelength of the electron beam is considerably shorter, and the horizontal resolution is higher than in measurement which uses the measurement light (for example, visible light) in the light measurement device 4, so the quantization error has little influence. Hence, the use of a mark pattern having edges parallel to the scanning direction of the stage 2 makes it possible to measure the mark position with high accuracy. This mechanism will be described in detail below with reference to FIGS. 5A and 5B.

FIG. 5A is a schematic view when electron beams 67A and 67B are scanned in the X-direction relative to a mark pattern 65 having edges that are not parallel to the scanning direction of the stage 2. In this case, the positions of the edges of the mark pattern 65 vary depending on the measurement position in the Y-direction. This means that the contrast of the detection signal degrades as the signal strength is increased by accumulating the measurement result in the Y-direction. This may generate a shift between a center position 68A between two peaks calculated from a differential waveform 69A of the detection signal, and the position of a center line 47A of the mark pattern 65 in the X-direction. Therefore, when the mark position is measured upon scanning the electron beam relative to the mark pattern 65 having edges that are not parallel to the scanning direction of the stage 2, a measurement error is generated, thus making it impossible to measure the mark position with high accuracy.

FIG. 5B is a schematic view when electron beams 67A and 67B are scanned in the X-direction relative to a mark pattern 66 having edges and a center line 47B that are parallel to the scanning direction of the stage 2. In this case, the positions of the edges of the mark pattern 65 are independent of the measurement position in the Y-direction. Accordingly, the peak positions of the differential waveform 69A remain the same independently of the measurement position in the Y-direction. This means that the contrast of the detection signal can improve as the signal strength is increased by accumulating the measurement result in the Y-direction. Upon this operation, a center position 68B between two peaks calculated from a differential waveform 69B of the detection signal coincides with the position of the center line 47B of the mark pattern 66 in the X-direction. Therefore, the mark position can be measured with high accuracy by electron beam measurement using a mark pattern having edges parallel to the Y-direction, as in the second pattern 50B shown in FIG. 1C.

The directions of the center lines of the first pattern 50A and second pattern 50B will be described. The drawing apparatus 100 measures the first pattern 50A and second pattern 50B which form the reference mark 5 using the light measurement device 4 and electron measurement device 24 to calculate the baseline. For this reason, when the center lines of the first pattern 50A and second pattern 50B are not identical, it is necessary to measure the interval between the center lines of the first pattern 50A and second pattern 50B in the measurement direction in baseline measurement, thus prolonging the measurement time. It can therefore be done to set the center lines of the first pattern 50A and second pattern 50B identical. Also, the drawing apparatus 100 scans the electron beam relative to the second pattern 50B of the reference mark 5 to obtain the position of the optical axis of the electron measurement device 24. Hence, the edges and center line of the second pattern 50B must be parallel to the scanning direction of the stage 2.

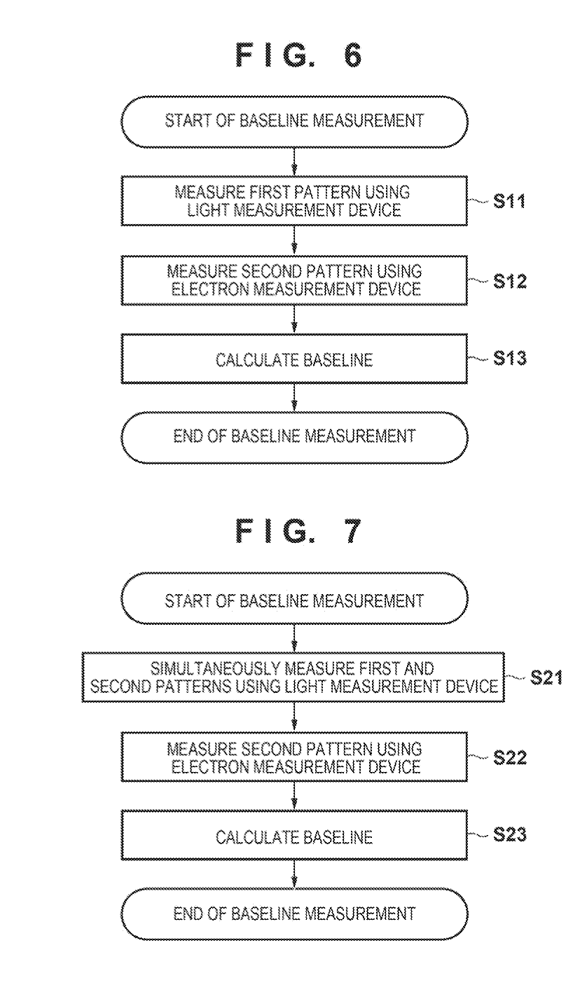

The sequence of baseline measurement according to the first embodiment will be described with reference to FIG. 6. As the measurement operation of the reference mark 5 starts, the drawing apparatus 100 executes the following steps in accordance with the sequence shown in FIG. 6. In step S11, the main controller 11 measures the mark position using the light measurement device 4 for a first pattern 50A having two side edges that are not parallel to the accumulation direction of the photoelectric conversion element 40 in the reference mark 5 to calculate the position of the reference mark 5.

In step S12, the main controller 11 measures the mark position using the electron measurement device 24 for a second pattern 50B having two side edges parallel to the scanning direction of the stage 2 in the reference mark 5 to calculate the position of the reference mark 5. In step S13, the main controller (processor) 11 calculates the positional relationship (baseline) between the optical axis of the light measurement device 4 and that of the electron measurement device 24 from the difference between the measurement results obtained by the electron optical system controller 7 and the light measurement device controller 8, and ends the baseline measurement operation.

With this operation, because the edges of the first pattern 50A are not parallel to the accumulation direction of the photoelectric conversion element 40, the influence of a quantization error generated by the light measurement device 4 can be reduced, as described earlier with reference to FIG. 1C. Also, because the edges of the second pattern 50B are parallel to the scanning direction of the stage 2, the contrast of the detection signal obtained by the electron measurement device 24 can be improved by accumulating this detection signal. Hence, the drawing apparatus 100 according to the first embodiment can measure the baseline with high accuracy based on the measurement results obtained by the light measurement device 4 and electron measurement device 24.

Further, in this embodiment, it is possible to shorten the time for the drawing apparatus 100 to measure the mark position using the electron measurement device 24, compared to the conventional scheme. In general, the electron beam has a spot size of several to several hundred nanometers, which is considerably smaller than the mark size (several ten micrometers), and the spot size (several ten micrometers) of the measurement light in the light measurement device 4. Hence, in the conventional scheme, the mark position is measured using the electron beam by repeatedly performing, for the entire region on the reference mark 5, an operation of deflecting the irradiation position of the electron beam in the X-direction after step movement of this position in the Y-direction. On the other hand, the drawing apparatus 100 according to this embodiment measures the electron beam only for the second pattern 50B of the reference mark 5, and uses a measurement region narrower than in the conventional scheme, thus shortening the measurement time.

As described above, in the drawing apparatus 100 according to this embodiment, the reference mark 5 includes a first pattern 50A having edges that are not parallel to the accumulation direction of the photoelectric conversion element 40, and a second pattern 50B having edges parallel to the scanning direction of the stage 2. Also, the center lines of the first pattern 50A and second pattern 50B are parallel to the scanning direction of the stage 2. The main controller 11 calculates the baseline based on the position measurement result of the first pattern 50A obtained by the light measurement device 4, and that of the second pattern 50B obtained by the electron measurement device 24. This reduces the influence of a quantization error generated by the light measurement device 4, and improves the contrast of the detection signal obtained by the electron measurement device 24 upon electron beam measurement. This, in turn, makes it possible to measure the baseline in a time shorter than that in the conventional method of measuring a plurality of mark positions upon minutely displacing an optical member. Also, compared to the method of inclining the accumulation direction of the photoelectric conversion element 40 with respect to the widthwise direction of the reference mark 5, degradation in contrast is suppressed more to measure the baseline with high accuracy. Hence, according to this embodiment, it is possible to provide a drawing apparatus 100 capable of aligning the positions of the electron beam and substrate 6 at high speed and high accuracy.

### Second Embodiment

A drawing apparatus 100 according to the second embodiment will be described with reference to FIG. 7. FIG. 7 shows the sequence of baseline measurement in the drawing apparatus 100 according to this embodiment. Since the configuration of a reference mark 5 is the same as in FIG. 1C described in the first embodiment, a description thereof will not be given, and only the sequence of measurement of the reference mark 5 will be described herein.

In step S21, a main controller 11 performs measurement using a light measurement device 4 for a first pattern 50A, having edges that are not parallel to the accumulation direction of a photoelectric conversion element 40, and a second pattern 50B, having edges that are parallel to the scanning direction of a stage 2, in the reference mark 5. The main controller 11 then calculates the position of the reference mark 5.

In step S22, the main controller 11 measures the position of the second pattern 50B, having two side edges parallel to the scanning direction of the stage 2, in the reference mark 5 using an electron measurement device 24 to calculate the position of the reference mark 5. In step S23, the main controller 11 calculates the positional relationship (baseline) between the optical axis of the light measurement device 4 and that of the electron measurement device 24 from the difference between the measurement results obtained by an electron optical system controller 7 and a light measurement device controller 8, and ends the baseline measurement operation.

The difference between the first and second embodiments lies in that in step S21 in the first embodiment, the position of the entire measurement region on the reference mark 5 is measured using the light measurement device 4, both for the first pattern 50A and the second pattern 50B. If edge roughness occurs in the pattern of the reference mark 5, a shift may occur in the measurement positions of the two side edges, and generate different amounts of errors in the position measurement results obtained by the first pattern 50A and second pattern 50B. At this time, when the baseline is calculated based on the measurement values of the first pattern 50A and second pattern 50B obtained by the light measurement device 4 and electron measurement device 24 as in the first embodiment, an error is generated in the baseline measurement result due to the difference in error associated with the edge roughness.

On the other hand, in the second embodiment, since position measurement is performed using the light measurement device 4 both for the first pattern 50A and second pattern 50B, the influence of the error associated with the edge roughness in the second pattern 50B of the reference mark 5 is reflected on the measurement result obtained by the light measurement device 4. Therefore, in calculating the baseline from the difference between the respective measurement values obtained by the light measurement device 4 and electron measurement device 24, it is possible to reduce the influence of the difference, in error associated with the edge roughness, between the first pattern 50A and second pattern 50B of the reference mark 5.

However, when position measurement is performed using the light measurement device 4 for a second pattern 50B having edges parallel to the scanning direction of the stage 2, a measure must be taken against generation of a quantization error. Hence, the measurement regions of the first pattern 50A and second pattern 50B, in the Y-direction, of the reference mark 5 must be determined in consideration of the amounts of generation of both a quantization error and an error associated with the edge roughness. When, for example, the measurement error due to the error associated with the edge roughness is larger than that due to the quantization error, the measurement region in the Y-direction is set wider in the second pattern 50B than in the first pattern 50A, thereby reducing the influence of the error associated with the edge roughness.

The drawing apparatus 100 according to this embodiment can calculate the baseline based on the position measurement results of the first pattern 50A and second pattern 50B obtained by the light measurement device 4, and that of the second pattern 50B obtained by the electron measurement device 24. This makes it possible to obtain the baseline with an accuracy higher than that in the first embodiment if the amount of generation of an error associated with the edge roughness of the pattern is different between the first pattern 50A and the second pattern 50B. Hence, according to this embodiment, it is possible to provide a drawing apparatus capable of aligning the positions of the electron beam and substrate 6 at high speed and high accuracy.

### Method of Manufacturing Article

A method of manufacturing an article according to an embodiment of the present invention is suitable for manufacturing various articles including a microdevice such as a semiconductor device and an element having a microstructure. This method can include a step of forming a latent image pattern on a photosensitive agent, applied on a substrate, using the above-mentioned drawing apparatus (a step of performing drawing on a substrate), and a step of developing the substrate having the latent image pattern formed on it in the forming step. This method can also include subsequent known steps (for example, oxidation, film formation, vapor deposition, doping, planarization, etching, resist removal, dicing, bonding, and packaging). The method of manufacturing an article according to this embodiment is more advantageous in terms of at least one of the performance, quality, productivity, and manufacturing cost of an article than the conventional methods.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-045783 filed Mar. 1, 2012, which is hereby incorporated by reference herein in its entirety.

What is claimed is:

1. A drawing apparatus which performs drawing on a substrate with a charged particle beam, the apparatus comprising:
a charged particle optical system configured to emit a charged particle beam onto the substrate;
a stage including a reference mark, and configured to hold the substrate and to be movable;
a first measurement device including an image taking optical system that takes an image of the reference mark with light, and configured to measure a position of the reference mark in a first direction perpendicular to an axis of the charged particle optical system;
a second measurement device configured to measure a position of the reference mark in the first direction, based on an amount of charged particle beams that arrives thereat from the reference mark on which the charged particle beam emitted from the charged particle optical system are incident; and
a processor configured to obtain a positional relationship between an optical axis of the image taking optical system and the axis of the charged particle optical system based on outputs from the first measurement device and the second measurement device,
wherein the reference mark includes a first region having a first edge inclined with respect to a second direction perpendicular to the first direction and the axis of the charged particle beam optical system, and a second region having a second edge parallel to the second direction, and
the processor is configured to obtain the positional relationship based on measurement result with respect to the first region obtained by the first measurement device, and measurement result with respect to the second region obtained by the second measurement device.

2. The apparatus according to claim 1, wherein the first measurement device is configured to measure the position of the reference mark by approximating an edge of the reference mark with a line.

3. The apparatus according to claim 1, wherein the first measurement device is configured to measure the position of the reference mark with respect to the first region and the second region.

4. The apparatus according to claim 1, wherein the second measurement device is configured to measure the position of the reference mark by obtaining a position of the second edge with a plurality of charged particle beams positions of which are different from each other in the second direction.

5. The apparatus according to claim 1, wherein the first region has a shape symmetric with respect to a line parallel to the second direction.

6. The apparatus according to claim 5, wherein the second region has a shape symmetric with respect to a line parallel to the second direction.

7. The apparatus according to claim 6, wherein the line for the first region and the line for the second region are same.

8. The apparatus according to claim 1, wherein the reference mark includes a plurality of the first region.

9. A method of manufacturing an article, the method comprising:
performing drawing on a substrate using a drawing apparatus;
developing the substrate having undergone the drawing; and
processing the developed substrate to manufacture the article,
wherein the drawing apparatus performs the drawing on the substrate with a charged particle beam, the apparatus including:
a charged particle optical system configured to emit a charged particle beam onto the substrate;
a stage including a reference mark, and configured to hold the substrate and to be movable;
a first measurement device including an image taking optical system that takes an image of the reference mark with light, and configured to measure a position of the reference mark in a first direction perpendicular to an axis of the charged particle optical system;
a second measurement device configured to measure a position of the reference mark in the first direction, based on an amount of charged particle beams that arrives thereat from the reference mark on which the charged particle beam emitted from the charged particle optical system are incident; and
a processor configured to obtain a positional relationship between an optical axis of the image taking optical system and the axis of the charged particle optical system based on outputs from the first measurement device and the second measurement device,
wherein the reference mark includes a first region having a first edge inclined with respect to a second direction perpendicular to the first direction and the axis of the charged particle beam optical system, and a second region having a second edge parallel to the second direction, and
the processor is configured to obtain the positional relationship based on measurement result with respect to the first region obtained by the first measurement device, and measurement result with respect to the second region obtained by the second measurement device.

10. A reference member including a reference mark for a drawing apparatus which performs drawing on a substrate with a charged particle beam, wherein
the reference mark includes a first region including a first edge inclined with respect to a predetermined direction parallel to a surface on which the reference mark is formed, and a second region including a second edge parallel to the predetermined direction.
